(19) United States
(12) Patent Application Publication
(10) Pub. No.: US 2015/0065062 A1
(43) Pub. Date: Mar. 5, 2015

(54) RADIO-ELECTRIC INHIBITOR SYSTEM FOR A COMMUNICATION DEVICE

(71) Applicant: TETRACEL S.A., Ciudad de Cordoba (AR)

(72) Inventor: Ricardo Matias De Goycoechea, Ciudad de Cordoba (AR)

(21) Appl. No.: 14/475,710

(22) Filed: Sep. 3, 2014

Related U.S. Application Data
(60) Provisional application No. 61/873,969, filed on Sep. 5, 2013.

(51) Int. Cl. H04B 1/40; H03G 3/30; H04W 24/02

(52) U.S. Cl. CPC H04B 1/40; H04W 24/02; H03G 3/3042
USPC 455/77

(57) ABSTRACT

A radio-electric inhibitor device having an adjustable gain chain of radio frequency device; a frequency mixing circuit connected to the an adjustable gain chain; a second adjustable gain chain of radio frequency device; and a central control unit independently connected to each one of the adjustable gain chain of radio frequency device, the frequency mixing circuit connected to the an adjustable gain chain; and the second adjustable gain chain of radio frequency device.

### CROSS-REFERENCE TO RELATED APPLICATIONS

This application claims the benefit of priority to U.S. Provisional Application No. 61/873,969 filed Sep. 5, 2013, the contents of which are incorporated herein by reference.

### FIELD OF THE INVENTION

The present disclosure relates to an inhibitor system for a communication device. More specific to a radio-electric inhibitor system for a communication device and method thereof.

### BACKGROUND OF THE INVENTION

Due to certain legal, regulatory, safety, governmental, military, commercial, and private, provisions, it is necessary that in certain areas (closed or open) to disable the operation of an electronic communication device, whether wireless or not; thus, the transmission and/or reception of any kind of communication through radio frequency signals with some type of modulation, may not operate.

The prior art discloses several devices that inhibit electronic communications basing their operation principle on noise generation, spurious signals, continuous or modulated waves, and/or static or dynamic, through the radio-electric spectrum of interest. Once the electronic communication is carried and/or broadcast, the communications are captured by, injected, or radiated to the electronic communication device, of which operation is intended to be hindered, trying to get as a result that said electronic communication device does not work properly.

Unfortunately, there are problems that arise from the application of the prior art devices:

For example, due to the nature of operation and the robustness of the communication systems intended to be hindered, these generations have to be performed at such levels that, once radiated, and in order to achieve the expected purpose, they have high levels of electric fields which in many cases exceed the maximum levels allowed by several regulations regarding nonionizing radiation. Therefore, devices may be a possible source of health problems for the people in the area where the operation of said electronic communication devices is intended to be hindered.

In addition, due to the nature of this generation, radiated or conducted signals are potential sources of interference over other electronic systems which are within and outside the area where the operation of said communication devices is intended to be hindered, therefore developing operation problems to said other systems.

Furthermore, due to the nature of this generation, the radiated or conducted signals are potential sources of interference over biometric devices. This becomes a serious risk for the people or living creatures who are carriers of said biometric systems, both inside or outside the area where the operation of said communication devices is intended to be hindered.

In addition, due to the nature of this generation, these systems are potential sources of interference for the receivers of the radio bases or relay stations of private communication systems or cell phones. They are from the systems intended to be hindered or third systems, which produces inconveniences with the communication traffic handling capacity of said systems, affecting other communication devices which are outside the area where the operation of said communication devices is intended to be hindered.

Furthermore, due to the nature of operation and the robustness of the communication systems intended to be hindered, these generations have to be performed at such levels that, once radiated and in order to achieve the expected purpose, they show high levels of electric fields, and therefore their implementation is difficult to be dimensioned being a possible source of problems for other communication devices which are outside the area where the operation of said communication devices is intended to be hindered.

For most legislations, the radio-electric spectrum band are licensed to companies that paid for said licenses and therefore any kind of radio-electric generation radiated is forbidden unless it is performed by the owner of the license and for the type of signal declared, so therefore this kind of solution could not be used since the type of radiated signal does not correspond with the one declared in the licenses, and in the event they coincide, they could only be radiated by the license owner but not by third parties.

Other institutions offer products or solutions where the operation is based on the conducted or broadcast emission of radio-electric signals in the range or ranges of the radio-electric spectrum used for the reception of radio-electric signals by the communication devices which operation is intended to be hindered. The origin of said broadcast or conducted signals is another portion or portions, continuous or discontinuous of the radio-electric spectrum different from the broadcast one, and that to said portion or portions, continuous or discontinuous, some kind of transformation has been performed over some of its parameters, like frequency, amplitude, and phase, among others.

The problems that arise from the application of this type of solutions are:

it is a technology only valid or frequency modulation FM and Third generation 3G systems.

this technology is not compatible with Time division multiple access TDMA technologies.

the operator of this kind of technology must be an entity which is owner of a license for radio-electric spectrum in order to broadcast this type of signal.

It is a kind of solution useful for one technology at a time and cannot operate in multi-technology simultaneously.

in the event the owner of this kind of device does not own a user's license for spectrum, the situation is a potential source of inconvenience in the quality of service for third parties outside the area where the operation of these communication devices is intended to be hindered.

due to the proper nature of the technology, to the application methodology and the robustness of the communication systems intended to be hindered, it is extremely difficult to dimension their range of action, and therefore it is a potential source of problems in the quality of service for third parties outside the area where the operation of these communication devices is intended to be hindered.

### SUMMARY OF THE INVENTION

The present invention relates to a radio-electric inhibitor device having an adjustable gain chain of radio frequency device; a frequency mixing circuit connected to the an adjustable gain chain;

a second adjustable gain chain of radio frequency device; and a central control unit independently connected to each one of the adjustable gain chain of radio frequency device, the frequency mixing circuit connected to the an adjustable gain chain; and the second adjustable gain chain of radio frequency device.

In addition, the present invention relates to a system inhibiting an electronic communication for a communication device including: a radio-electric inhibitor device having: an adjustable gain chain of radio frequency device; a frequency mixing circuit connected to the an adjustable gain chain; a second adjustable gain chain of radio frequency device; and a central control unit independently connected to each one of the adjustable gain chain of radio frequency device, the frequency mixing circuit connected to the an adjustable gain chain; and the second adjustable gain chain of radio frequency device; a capturing device; a physical or radio electric link having a first end connected to the capturing device and a second end connected to the radio frequency device of the radio-electric inhibitor device; a second electric link device having a first end connected to the second radio frequency device of the inhibitor device.

### BRIEF DESCRIPTION OF THE DRAWINGS

For a fuller understanding of the nature and objectives of the invention, reference should be made to the following detailed description, taken in connection with the accompanying drawings, in which:

FIG. 1 shows a diagram of the radio-electronic inhibitor system according to an embodiment of the present invention;

FIG. 2 shows examples of downlinks for the system of FIG. 1;

FIG. 3 shows a diagram of the two waves received by the communication device;

FIG. 4a shows examples of digital modulation constellation without EVM;

FIG. 4b shows examples of digital modulation constellation with EVM;

FIG. 5 shows the radio-electric inhibitor system in a disassembled position;

FIG. 6 shows the radio-electric inhibitor system in a partially assembled position; and

FIG. 7 shows the radio-electric inhibitor system in a disassembled position.

### DETAILED DESCRIPTION OF THE INVENTION

In the present invention the term “operation” refers to receive and/or establish a radio-electric link with another radio-electric and/or communication device which may be both within and outside the specific area, whether over the earth surface, aerial, or spatial, so that no information reception and/or transfer of any kind can be performed, whether user contents, signaling or typical signals from the communication system over which said radio-electric device operates.

in the present invention the terms “communication device” and “electronic communication device” refer to wireless or not wireless communication devices.

After a long period of research and development, the present inventor has developed a system which avoids that a communication device transmitting and/or receiving information of any kind through radio frequency signals with some type of modulation, to operate so that no information reception and/or transfer of any kind can be performed. Whether user contents, signaling or typical signals from the communication system over which said radio-electric device operates, a radio-electric inhibition technology has been developed under the premise that said technology or its application does not produce the following problems or is a potential source of the following problems:

That produces an exposure to radiation on people or other living creatures that goes beyond the limits allowed by the several international legislations.

That is not a source of generation for radiated or conducted radio-electric signals, so that no licenses over radio-electric spectrum are violated nor its application requires to obtain any license.

That can be delimited as regards to the scope and field of action, therefore it will not interfere with the operation of communication devices which are outside the field of action.

That is not able to interfere with any other electronic or communication system which is within or outside the field of action.

That is not able to interfere with any biometric system which is within or outside the field of action.

That is not able to interfere or disturb the performance of radio-base receptors of telecommunication systems no matter the technology these systems operate with.

The radio-electric inhibitor device C according to an embodiment of the present invention includes an adjustable gain chain of radio frequency device D (hereafter called radio frequency device D); a frequency mixing circuit E connected to the radio frequency device D; a frequency mixing circuit E (hereafter called mixing circuit E) connected to the radio frequency device D; a second an adjustable gain chain of radio frequency device F (hereafter called second radio frequency device F); and a central control unit G. All of the elements of the inhibitor device C according to the present invention are encased by a metallic casing.

The system inhibiting an electronic communication for a communication device according to an embodiment of the present invention includes a capturing device A; a physical or radio electric link B (hereafter called electric link B) connected to the capturing device A; The electric link B is operatively connected to the radio frequency device D of the radio-electric inhibitor device C. A second electric link device I is operatively connected to the second radio frequency device F of the inhibitor device C. A second radiation device is connected to the second link I.

The capturing device A captures and/or radiates the radiated electromagnetic waves of the signals (downlink) present in the radio-electric spectrum in which it receives the communication device M which operation is intended to be hindered.

The capturing device A may be, for example, an antenna, a satellite dish, or any f radiofrequency physical link that links to the original signal source.

The signal (downlink) is generated by the generator devices (not shown) of said communication devices M, whether within or outside the area where the operation of the communication devices is intended to be hindered, whether is over the earth surface, aerial, or spatial.

The captured signals CS are carried to the entry of the radio-electric inhibitor device C by the electric link B. The electric link B may be, for example a coaxial cable, a multi-pair cable, or a radial link in any other radio-electric band.

Once inside the inhibitor device C, the captured signals CS are adapted in amplitude by using an adjustable gain chain of radio frequency device D. The adjustable gain chain of radio frequency device D may be, for example, a radiofrequency low noise amplifier with a pin diode adjustable attenuator, that enhance the CS level with to a specific desired level.

After leaving the radio frequency signal device D, the captured signal is then treated in their phase parameter with a frequency mixing circuit E by heterodyne reduction or by a digital treating circuit of signals. The circuit E can be, but not limited to, an analog circuit composed by an input radiofrequency matching and filtering circuit that adapts impedances and/or eliminates unwanted CS radiofrequency spectrum, an input radiofrequency mixer that heterodinizes the radiofrequency CS into intermediate frequency CS spectrum, an intermediate frequency input matching and filtering circuit that adapts impedances and/or eliminates unwanted intermediate CS spectrum, an intermediate frequency filter that selects only the desired CS spectrum, an intermediate frequency output matching and filtering circuit that adapts impedances and/or eliminates unwanted intermediate CS frequency spectrum, an output radiofrequency mixer that heterodinizes the intermediate frequency CS into radiofrequency CS spectrum, a radiofrequency output matching and filtering circuit that adapts impedances and/or eliminates unwanted CS radiofrequency spectrum, with the input radiofrequency mixer being driven by a programmable continuous wave non modulated signal source like a frequency synthesizer controlled by circuit G, and with the output radiofrequency mixer controlled by a second programmable modulated signal source like a frequency modulator controlled by circuit G.

Once the captured signals CS are treated in-phase, the signals are amplified again by using a second radio frequency device F. The second radio frequency device F may have the capacity to deliver radio frequency power at the levels required as a result of the application engineering or engineer project. Circuit F may be, for example, a radiofrequency gain block composed by a single or multiple radiofrequency transistors array in order to provide the CS signal with an appropriated amplitude.

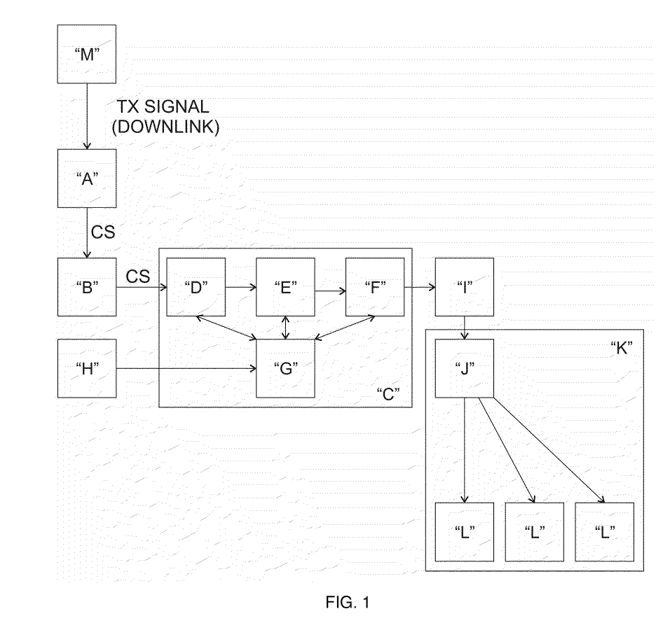

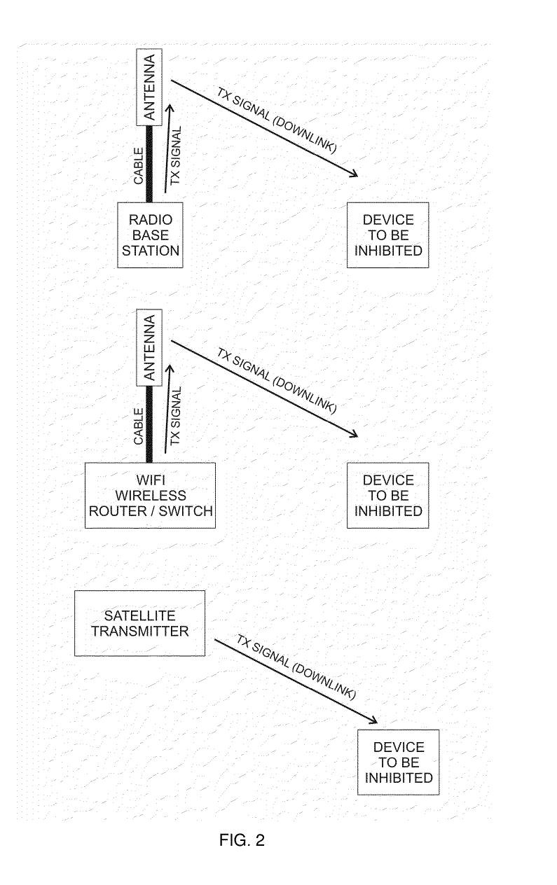

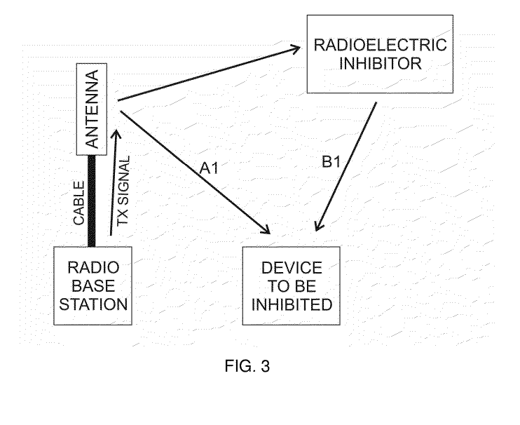

The inhibitor device C is controlled by a central control unit G (FIG. 1), which controls the operating parameters of inhibitor device C. The central control G may be, for example, a microcontroller or microprocessor based logic unit that provides the internal control and supervision, and provides the interface with the user to adjust the operational parameters and/or read function status alarms.

The central control unit G is energized by an energy source H (FIG. 1). The energy source H may be, for example, a power supply, a battery, a UPS system, an energy system of solar panel, or combination thereof.

Once the signals are amplified and treated in their phase parameter, the same are carried by a second physical or radio-electric link I. The second physical or radio-electric link I may be, for example, a coaxial cable, a multi-pair cable, or radial link in any other radio-electric band.

The signals are then radiated again, by a device that radiates electromagnetic waves J, for example, an antenna or an antenna arrangement (active and/or passive). The signals are radiated within the area of interest K.

The operation of the communication devices L is intended to be hindered, with a level intensity that equals or surpasses the present levels of the original signals coming originally from the transmitters of the communication systems M involved, with the objective The radiated signals by the antenna J are predominant in power at the moment they are captured by the receivers of the communication devices L which function is intended to be hindered,

Thus, the receivers of said communication devices L cannot correctly interpret the total received information, since they are receiving simultaneously two wave sources, the one coming directly from the generation source A1, and the wave source treated by the radio-electric inhibitor.

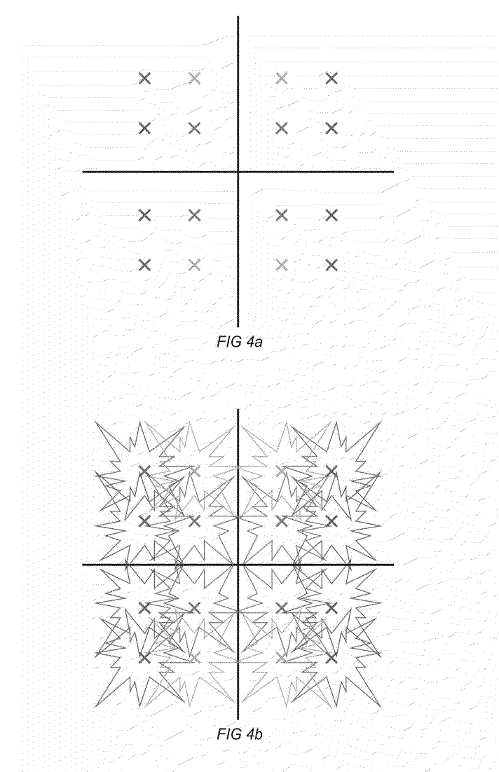

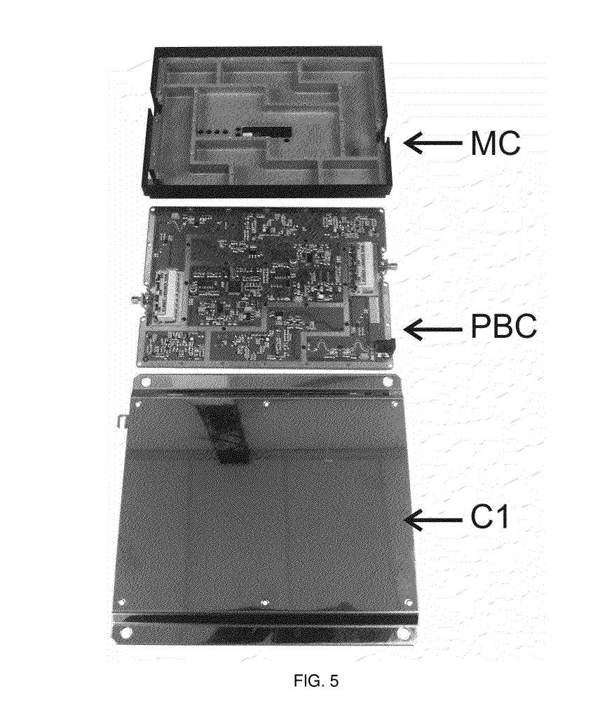

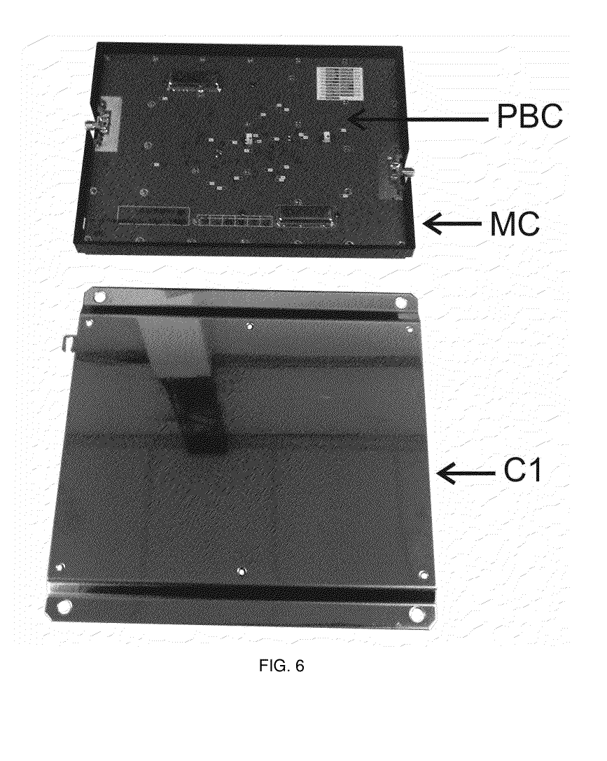

The addition of both wave sources received with different levels create demodulation errors in the receivers of the communication device L, for example, an increase of the error vector magnitude (EVM) in a constellation in digital modulations, as shown in FIG. 4b, thus impeding them to operate properly.

The inhibitor device C includes a printed circuit (PCB) with the elements D, E, F, and G assembled and connected inside a metal casing MC. The metal casing MC acts as a mechanical support and a radio-electric shielding.

A clamp C1 serves as a cover to the inhibitor device C and as a mechanical fixing element for installation.

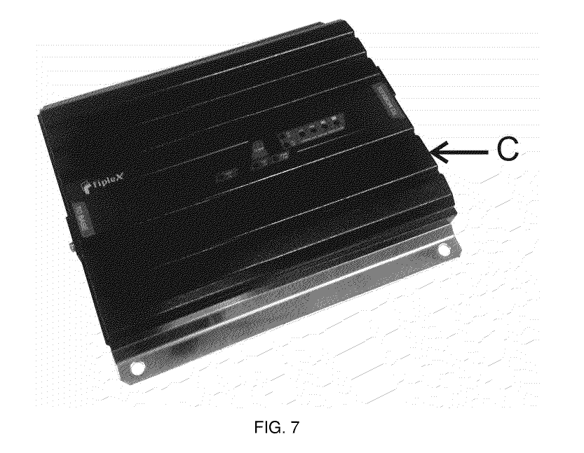

The complete radio-electric inhibitor device C is shown in FIG. 7.

The radio-electric inhibitor developed presents the following outstanding characteristics:

It does not generate signals independently, it feeds from the downlink signals which are in the radio-electric spectrum, and therefore its operation does not infringe any regulation related to radio-electric spectrum licenses.

Thanks to the functioning philosophy, the wave sources that have to arrive to the communication device which operation is intended to be impeded, must be of similar levels, therefore the radiated power is not increased, and people and other human beings are not exposed to nonionizing radiations greater than the ones existing without the radio-electric inhibitor working.

Since it only operates with downlink signals, there is no treatment over the uplink spectrum, which is the one received by the radio base receivers or relay stations, and therefore said receivers functioning is not affected without affecting the quality of the communication nets and without affecting not involved third parties.

Since it only operates with downlink signals and that the power radiated is similar to the downlink signals present without the radio-electric inhibitor working, it does not affect biometric devices or any other electronic systems, within or outside the area of action of the radio-electric inhibitor.

Thanks to the functioning philosophy and that the wave fronts that have to arrive to the communication device which functioning is intended to be impeded, should be of similar levels, its operation is limited to the area of interest, thanks to the attenuation of free space endured by the radiated electromagnetic waves.

What is claimed is:

1. A radio-electric inhibitor device comprising:
an adjustable gain chain of radio frequency device;
a frequency mixing circuit connected to the an adjustable gain chain;
a second adjustable gain chain of radio frequency device; and
a central control unit independently connected to each one of the adjustable gain chain of radio frequency device, the frequency mixing circuit connected to the an adjustable gain chain; and the second adjustable gain chain of radio frequency device.

2. The radio-electric inhibitor device according to claim 1, further including a metallic casing to encase the central control unit, the adjustable gain chain of radio frequency device, the frequency mixing circuit connected to the an adjustable gain chain; and the second adjustable gain chain of radio frequency device.

3. A system inhibiting an electronic communication for a communication device comprising:
a radio-electric inhibitor device having: an adjustable gain chain of radio frequency device; a frequency mixing circuit connected to the an adjustable gain chain; a second adjustable gain chain of radio frequency device; and a central control unit independently connected to each one of the adjustable gain chain of radio frequency device, the frequency mixing circuit connected to the an adjustable gain chain; and the second adjustable gain chain of radio frequency device;
a capturing device;
a physical or radio electric link having a first end connected to the capturing device and a second end connected to the radio frequency device of the radio-electric inhibitor device;
a second electric link device having a first end connected to the second radio frequency device of the inhibitor device; and
a second radiation device connected to a second end of the second link.
